(19) United States
(12) Patent Application Publication
(10) Pub. No.: US 2026/0177646 A1
(43) Pub. Date: Jun. 25, 2026

(54) MEASURING ASSEMBLY

(71) Applicant: FRABA B.V., SG HEERLEN (NL)

(72) Inventor: MATTHIAS LANSING, WUERSELEN (DE)

(73) Assignee: FRABA B.V., SG HEERLEN (NL)

(21) Appl. No.: 19/123,774

(22) PCT Filed: Oct. 26, 2022
(86) PCT No.: PCT/EP2022/079918

§ 371 Date: Apr. 24, 2025

(51) Int. Cl. G01R 33/09; G01D 5/14; G01R 33/00; G01R 33/07

(52) U.S. Cl. CPC G01R 33/093; G01D 5/145; G01R 33/0005; G01R 33/0017; G01R 33/0029; G01R 33/07; G01R 33/09; G01R 33/096

(57) ABSTRACT

A measuring arrangement includes a rotationally or translationally movable object and a measuring system which measures the object's movement. The measuring system includes an exciter unit connected to the object which has an exciter magnet, a Wiegand sensor and a magnetoresistive sensor unit which interact with the exciter magnet's magnetic field, a switching unit electrically connected to the Wiegand sensor, and an additional resistor. The magnetoresistive sensor unit is offset and/or rotated relative to the Wiegand sensor. The voltage divider has a first and a second connection for supplying the voltage divider, a magnetoresistive element, and a measuring point. The additional resistor is electrically connected via the switching unit to the measuring point and to a third or a fourth connection. The switching unit evaluates the Wiegand sensor's voltage pulses. A switching between the third and fourth connection takes place as a function of the voltage pulses polarity.

### CROSS REFERENCE TO PRIOR APPLICATIONS

This application is a U.S. National Phase application under 35 U.S.C. § 371 of International Application No. PCT/EP2022/079918, filed on Oct. 26, 2022. The International Application was published in German on May 2, 2024 as WO 2024/088529 A1 under PCT Article 21(2).

### FIELD

The present invention relates to a measuring arrangement with an object that can be rotated around a rotational axis or moved in a translational manner, and a measuring system for measuring an object movement, the measuring system comprising: an exciter unit that is connected to the object in a rotationally fixed manner and which comprises at least one permanent-magnetic exciter magnet, a Wiegand sensor that interacts with a magnetic field of the exciter magnet, a magnetoresistive sensor unit, which interacts with the magnetic field of the exciter magnet and is offset and/or twisted relative to the Wiegand sensor, wherein the magnetoresistive sensor unit comprises a voltage divider with a first connection and a second connection for supplying the voltage divider, at least one magnetoresistive element, and a measuring point.

### BACKGROUND

Such measuring arrangements are used in the form of a rotational angle measuring arrangement to measure the rotational movement of an object, i.e., a shaft rotating around a rotational axis, wherein rotational angle measuring systems are also often referred to as angle measuring devices, rotational angle sensors or rotary encoders. Such rotational angle measuring arrangements are in particular used to control and monitor electric motors, in particular servo motors, in machines, systems or vehicles. Such a rotational angle measuring arrangement is described, for example, in WO 2020/015834 A1, wherein the rotational angle measuring arrangement comprises a shaft rotating around a rotational axis, with four exciter magnets attached thereto, a Wiegand sensor, and a further sensor for determining the direction of rotation of the shaft. The exciter magnets are attached to a plate-like carrier element that is firmly connected to the rotating shaft and rotate along a circular path. The Wiegand sensor and the other sensor are both arranged on a rigidly arranged carrier element. The other sensor is offset from the Wiegand sensor and is configured as a Hall sensor. DE 10 2012 008 888 A1 also describes a rotational angle measuring arrangement with a Wiegand sensor and a further sensor, wherein the further sensor is configured as a magnetoresistive sensor. The rotational angle measurement arrangement comprises a bipolar exciter magnet which is arranged on an end face of a rotating shaft and which rotates together with the shaft around a rotational axis. In DE 10 2012 008 888 A1, both sensors are aligned, i.e., they are not offset from each other and are not twisted relative to each other.

When the angle of rotation measuring device is in operation, the voltage pulses of the Wiegand sensor and the sensor signal of the magnetoresistive sensor unit are usually evaluated in a control unit. To determine the direction of rotation of the rotating shaft, the sensor signal of the magnetoresistive sensor unit is compared with zero at the rotational positions at which a voltage pulse of the Wiegand sensor with a corresponding polarity occurs, i.e., it is determined whether the sensor signal comprises a negative sensor value or a positive sensor value. It can be defined, for example, that if there is a voltage pulse from the Wiegand sensor with a positive polarity and a positive sensor value from the magnetoresistive sensor unit, and if there is a voltage pulse from the Wiegand sensor with a negative polarity and a negative sensor value from the magnetoresistive sensor unit, the shaft will rotate in a first direction of rotation, for example, clockwise. The shaft otherwise rotates in a second direction, i.e., counterclockwise, if there is a voltage pulse from the Wiegand sensor with the positive polarity and a negative sensor value from the magnetoresistive sensor unit, as well as if there is a voltage pulse from the Wiegand sensor with the negative polarity and a positive sensor value from the magneto-resistive sensor unit. In measuring arrangements with a translationally movable object, the voltage pulses of the Wiegand sensor and the sensor signal of the magnetoresistive sensor unit are also evaluated in a control unit and the direction of movement of the translationally moved object is determined by the principle described on the basis of the rotating shaft.

In the case of a displaced or twisted arrangement of the magnetoresistive sensor unit relative to the Wiegand sensor, the sensor signal of the magnetoresistive sensor unit is compressed, distorted and/or shifted so that the problem arises that the sensor signal of the magnetoresistive sensor unit in the range of a voltage pulse of the Wiegand sensor in one direction or direction of rotation is close to zero. If this occurs, it is no longer possible to reliably determine whether the sensor signal of the magnetoresistive sensor unit has a negative or a positive sensor value. In the extreme case, the sensor signal of the magnetoresistive sensor unit could be compressed, distorted and/or shifted so that, when a shaft is rotating, two voltage pulses of the Wiegand sensor with the same polarity are present in the same area, i.e., both in the negative region or in the positive region, and differ only depending on the direction of rotation. The direction of rotation of the rotating shaft in this position or in these positions can as a result no longer be determined in a simple manner as explained above. Determining the direction of rotation, i.e., the signal evaluation, is then only possible using a considerably more complex method. A corresponding problem also exists in the case of a translationally moved object.

### SUMMARY

An aspect of the present invention is to provide a measuring arrangement with an arrangement of the magnetoresistive sensor unit that is offset and/or rotated with respect to the Wiegand sensor with which the signal evaluation of the sensors can be carried out with relatively low effort.

In an embodiment, the present invention provides a measuring arrangement which includes an object which is configured to rotate around a rotational axis or which is configured to be translationally movable, and a measuring system which is configured to measure a movement of the object. The measuring system comprises an exciter unit which is connected to the object, the exciter unit comprising at least one permanent-magnet exciter magnet, a Wiegand sensor which is configured to interact with a magnetic field of the at least one permanent-magnet exciter magnet, a magnetoresistive sensor unit which is configured to interact with the magnetic field of the at least one permanent-magnet exciter magnet and which is arranged at least one of offset and rotated relative to the Wiegand sensor, a switching unit which is electrically connected to the Wiegand sensor, and an additional resistor. The magnetoresistive sensor unit comprises at least one voltage divider. The at least one voltage divider comprises a first connection and a second connection for supplying the at least one voltage divider, at least one magnetoresistive element, and at least one measuring point. The additional resistor is electrically connected to the at least one measuring point and is configured to be electrically connected via the switching unit either to a third connection or to a fourth connection. The switching unit is configured to evaluate voltage pulses of the Wiegand sensor so that a switching between the third connection and the fourth connection takes place as a function of a polarity of the voltage pulses of the Wiegand sensor.

### BRIEF DESCRIPTION OF THE DRAWINGS

The present invention is described in greater detail below on the basis of embodiments and of the drawings in which:

FIG. 1 shows a cross-section of an embodiment of a measuring arrangement according to the present invention;

FIG. 2 shows a schematic representation of a bridge circuit and the switching unit of the measuring arrangement from FIG. 1;

FIG. 3 shows a diagram of the sensor signals of a Wiegand sensor and a magnetoresistive sensor unit of the measuring arrangement from FIG. 1; and

FIG. 4 shows a schematic representation of a voltage divider and the switching unit of the measuring arrangement from FIG. 1.

### DETAILED DESCRIPTION

The measuring arrangement according to the present invention comprises an exciter unit with at least one exciter magnet for generating an exciter magnetic field. In a measuring arrangement designed as a rotational angle measuring arrangement, the permanent magnetic exciter magnet is typically attached to a rotatable shaft so that the alternating exciter magnetic field is generated by a rotational movement of the shaft. The exciter magnet can, however, alternatively also be attached to a translationally movable object which, for example, moves linearly back and forth. The movement of the permanent magnetic exciter magnet generates an alternating exciter magnetic field in either case, i.e., an exciter magnetic field in which the polarity continuously reverses so that the (effective) direction of the field lines continuously changes over time.

The measuring arrangement according to the present invention comprises a Wiegand sensor with generally a pulse wire (also referred to as a Wiegand wire) and a coil arrangement radially enclosing the pulse wire. The magnetization direction of the pulse wire abruptly flips under the influence of an external magnetic field as soon as a specific trigger field strength is exceeded. The Wiegand wire maintains its magnetic polarity up to a certain point and flips to the opposite polarity when exposed to a reverse external magnetic field. This generates a short voltage pulse with a defined electrical energy in the coil arrangement.

The measuring arrangement according to the present invention further comprises a magnetoresistive sensor unit, for example, a TMR sensor or a GMR sensor, and is used to continuously measure the magnetic field of the exciter magnet. Magnetoresistive sensors are based on the magnetoresistive effect, wherein the electrical resistance of a material changes when an external magnetic field is applied. The change in electrical resistance is used to measure the external magnetic field.

The magnetoresistive sensor unit includes a voltage divider with a first connection and a second connection for supplying the voltage divider, at least one magnetoresistive element, and a measuring point. The sensor signal is obtained from the measured value at the measuring point.

The present invention provides that an additional electrical resistance is electrically connected to the measuring point, wherein the additional resistance can be optionally electrically connected via a switching unit to a third connection with a third voltage level or to a fourth connection with a fourth voltage level, and wherein the switching unit is electrically connected to the Wiegand sensor, evaluates the voltage pulses of the Wiegand sensor, and that the switching between the third connection and the fourth connection is carried out depending on the polarity of the voltage pulses of the Wiegand sensor.

The additional resistor can be used to displace the sensor signal of the magnetoresistive sensor unit in a defined manner so that the sensor signal comprises either a positive sensor value or a negative sensor value in the event of a voltage pulse of the Wiegand sensor, thereby allowing the direction of the object, for example, the direction of rotation of a shaft, to be determined reliably and with low effort. The additional resistor is a two-pole passive electrical component that realizes an ohmic resistance in electrical and electronic circuits.

The switching unit, i.e., the optional connection of the additional resistor to the third connection or to the fourth connection, can be used to shift the sensor signal in one direction or the other. The third connection can, for example, be electrically connected to the first connection and the fourth connection can, for example, be electrically connected to the second connection, so that the switching is performed by the switching unit between the first connection and the second connection.

By operating the switching unit depending on the polarity of the voltage pulse of the Wiegand sensor, it can be provided that in the ranges of motion, i.e., in the angle of rotation ranges in the case of a rotating shaft, in each of which a voltage pulse of the Wiegand sensor with the same polarity is present, the sensor signal of the magnetoresistive sensor unit has an opposite polarity to one another. The direction of movement of the object can be determined based thereon since the voltage pulses of the Wiegand sensor with the same polarity can be differentiated from one another.

In an embodiment of the present invention, a first voltage divider and a second voltage divider can, for example, be provided which together form a bridge circuit having two parallel-connected bridge arms, wherein each bridge arm comprises two series-connected magnetoresistive elements and a measuring point arranged between the two magnetoresistive elements, wherein one of the two measuring points is electrically connected to an additional resistor. The sensor signal is obtained by calculating the measured values at the two measuring points. The measurement signals are in this case supplied to a comparator, for example, and the sensor signal is calculated.

Only a single voltage divider is alternatively provided which comprises the magnetoresistive element and a resistor with a fixed resistance, wherein the magnetoresistive element and the resistor are connected in series. The measuring point is arranged between the magnetoresistive element and the resistor.

In an embodiment of the present invention, a voltage pulse of the Wiegand sensor caused in a first direction of the rotating or translationally moving object at a first position and a voltage pulse of the Wiegand sensor caused in a second direction opposite to the first direction of the rotating or translationally moving object at a second position can, for example, have the same polarity, wherein the sensor signal of the magnetoresistive sensor unit comprises a negative value at the first position and a positive value at the second position. A comparator electrically connected to the two measuring points of the bridge circuit in this case, for example, outputs a sensor signal from the magnetoresistive sensor unit, wherein it is evaluated whether the sensor signal comprises a positive or a negative sensor value.

A voltage pulse of the Wiegand sensor caused in a first direction of the rotating or translationally moving object at a first position and a voltage pulse of the Wiegand sensor caused in a second direction opposite to the first direction of the rotating or translationally moving object at a second position alternatively have the same polarity, wherein at the first position the measured value of the measuring point is greater than a predefined voltage value, and at the second position the measured value of the measuring point is less than the predefined voltage value. The predefined voltage value is, for example, 50% of the supply voltage present at the first connection. Only the value at the measuring point is in this case compared with a predefined voltage value. In contrast to the first variant, it is not the sensor signal that is considered, but the values at the measuring point of the voltage divider.

Both alternatives are used to differentiate the direction of voltage pulses of the Wiegand sensor with the same polarity, wherein the sensor signal of the magnetoresistive sensor unit is compared with zero, i.e., it is determined whether the sensor signal comprises a negative sensor value or a positive sensor value, and the measured value at the measuring point is compared with a predefined voltage value. Several voltage pulses from the Wiegand sensor with the same polarity in both cases result in defined values that deviate from each other depending on the direction of the rotating or translating object.

A measuring arrangement is described below with reference to the attached drawings.

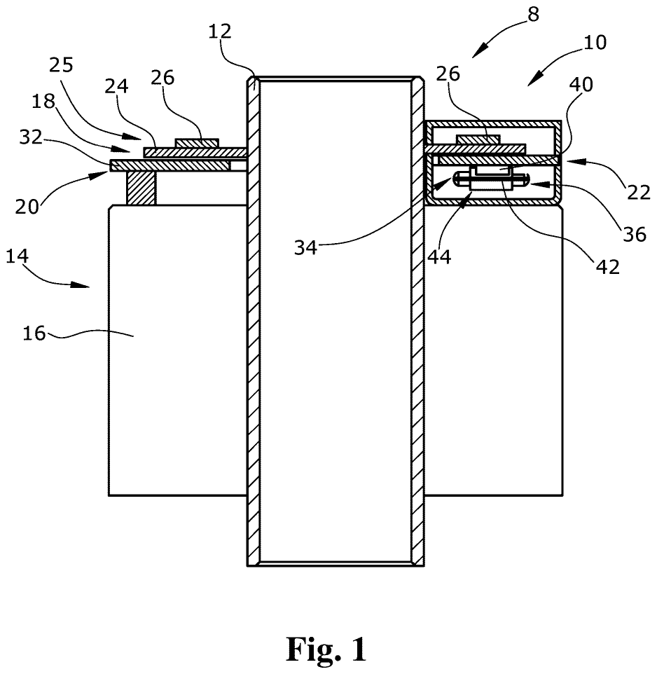

FIG. 1 shows a measuring arrangement 8 which is designed as a rotational angle measuring arrangement with a rotating shaft 12, which forms the rotating object, and a measuring system 10 which is designed as a rotational angle measuring system for measuring the rotational movement of the shaft 12. In the present embodiment example, the shaft 12 is a hollow shaft which extends essentially in the axial direction and is driven by a drive motor 14 with a static motor housing 16. The measuring system 10 comprises a rotor unit 18, a stator unit 20, and a magnetic shielding arrangement 22.

The rotor unit 18 comprises a rotor plate 24 which radially encloses the shaft 12 and is attached directly to the shaft 12. The rotor unit 18 is thus non-rotatably connected to the shaft 12. An exciter unit 25 is arranged on the rotor plate 24, which comprises four exciter magnets 26 distributed evenly along the circumference of the rotor plate 24, which rotate along a circular path when the shaft 12 rotates. Only two of the four exciters magnets 26 are shown in FIG. 1.

The stator unit 20 comprises a stator plate 32 which radially encloses the shaft 12. A sensor device 34 is arranged on the stator plate 32 and comprises a Wiegand sensor 36 and an integrated circuit with an evaluation unit and a magnetoresistive sensor unit 40. The integrated circuit further comprises a control logic (which is not shown in detail) and a power management (which is also not shown in detail) which provide an energy-autonomous operation of the sensor device 34 via the electrical energy obtained from the Wiegand sensor 36. The evaluation unit is also connected in terms of signal technology to a non-volatile data memory (which is not shown in detail) in which a revolution count value is stored and read out by the evaluation unit.

The sensor device 34 is positioned radially so that the Wiegand sensor 36 and the magnetoresistive sensor unit 40 measure the magnetic fields of the exciter magnets 26 when the shaft 12 rotates, which rotate with the shaft 12 and are thus guided past the Wiegand sensor 36 and the magnetoresistive sensor unit 40.

The Wiegand sensor 36 comprises a Wiegand wire 42 and a coil arrangement 44 radially surrounding the Wiegand wire. The magnetization direction of the Wiegand wire 42 folds around abruptly under the influence of an external magnetic field as soon as a specific triggering field strength is exceeded. In doing so, the Wiegand wire 42 retains its magnetic polarity up to a certain point and flips to the opposite polarity when exposed to a reversed external magnetic field. This generates a short voltage pulse with a defined electrical energy in the coil arrangement 44. The polarity of the voltage pulse of the coil arrangement 44 depends on the direction in which the Wiegand wire 42 flips.

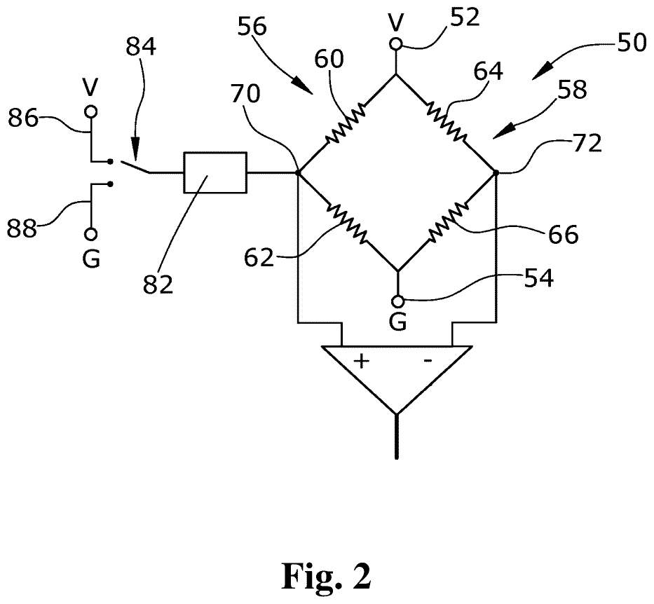

The magnetoresistive sensor unit 40 is offset in the circumferential direction and thus rotated in accordance with the angular offset to the Wiegand sensor 36 and is based on the magnetoresistive effect, wherein the electrical resistance of a material changes when an external magnetic field is applied. The change in electrical resistance is used to measure the external magnetic field. FIG. 2 shows that the magnetoresistive sensor unit 40 comprises two voltage dividers 46, 48 forming a bridge circuit 50, a first connection 52, to which the supply voltage is in contact, and a second connection 54, to which the earth is in contact, for supplying the bridge circuit 50. The bridge circuit 50 comprises two bridge branches 56, 58 which are connected in parallel, wherein each bridge branch 56, 58 comprises two magnetoresistive elements 60, 62, 64, 66 which are connected in series and a respective measuring point 70, 72 arranged between the two magnetoresistive elements 60, 62, 64, 66. The measuring points 70, 72 are electrically connected to a comparator, wherein the measuring point values of the two measuring points 70, 72 are offset to form a sensor signal of the magnetoresistive sensor unit 40.

The present invention provides that an additional resistor 82 is electrically connected to one of the two measuring points 70. The additional resistor 82 is also electrically connected to a switching unit 84, through which the additional resistor 82 can optionally be electrically connected to a third connection 86 or a fourth connection 88. In the present case, the third connection 86 is electrically connected to the first connection 52 and the fourth connection 88 is electrically connected to the second connection 54 so that the supply voltage V is present at the third connection 86 and the ground G is present at the fourth connection 88. As a result, the additional resistor 82 is connected in parallel either to the one magnetoresistive element 60 of the first bridge branch 56 or to the other magnetoresistive element 62 of the first bridge branch 56. The switching unit 84 is electrically connected to the Wiegand sensor 36, wherein the switching of the switching unit 84 is dependent on the polarity of the voltage pulses of the coil arrangement 44.

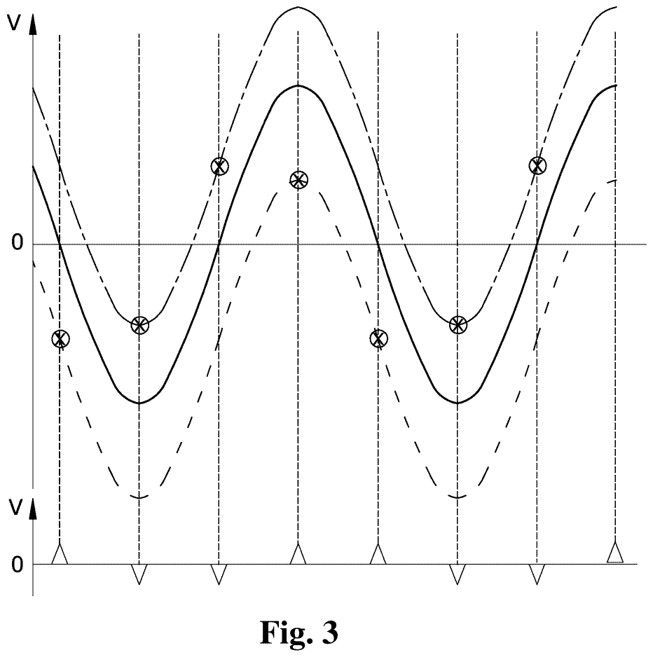

FIG. 3 shows a diagram with a plurality of plotted courses of the sensor signal of the magnetoresistive sensor unit 40 and a diagram with a plotted course of the voltage pulses of the Wiegand sensor 36. The solid line shows the course of the sensor signal of the magnetoresistive sensor unit 40 without the additional resistor 82. The dash-dot line shows the course of the sensor signal of the magnetoresistive sensor unit 40 with a parallel connection of the additional resistor 82 to the magnetoresistive element 60, i.e., the dashed line shows the course of the sensor signal of the magnetoresistive sensor unit 40 with a parallel connection of the additional resistor 82 to the magnetoresistive element 62, i.e., the connection of the additional resistor 82 to the second connection 54.

As explained above, when the additional resistor 82 is connected to the second connection 54, i.e., when the polarity of the voltage pulse of the Wiegand sensor 36 is positive, the original sensor signal, i.e., without the additional resistor 82, is shifted downward as viewed in the Y direction, and the sensor value of the sensor signal at the rotational position of the corresponding voltage pulse of the Wiegand sensor 36 is evaluated based on the downwardly shifted dashed line. In contrast, when the additional resistor 82 is connected to the first connection 52, i.e., with a negative polarity of the voltage pulse of the Wiegand sensor 36, the original sensor signal is shifted upwards as viewed in the Y-direction and the sensor value of the sensor signal is evaluated at the rotational position of the corresponding voltage pulse of the Wiegand sensor 36 using the upwardly shifted dashed dot line.

This configuration provides a clear assignment of the direction of rotation for each voltage pulse, wherein a positive sensor value of the sensor signal is present for a rotation in a first direction of rotation for a voltage pulse with a positive polarity and a negative sensor value of the sensor signal is present for a voltage pulse with a negative polarity. In contrast, a rotation in a second direction of rotation, opposite to the first, results in a negative sensor value of the sensor signal for a voltage pulse with a positive polarity and a positive sensor value of the sensor signal for a voltage pulse with a negative polarity. This allows the direction of rotation of the shaft to be determined for each voltage pulse of the Wiegand sensor.

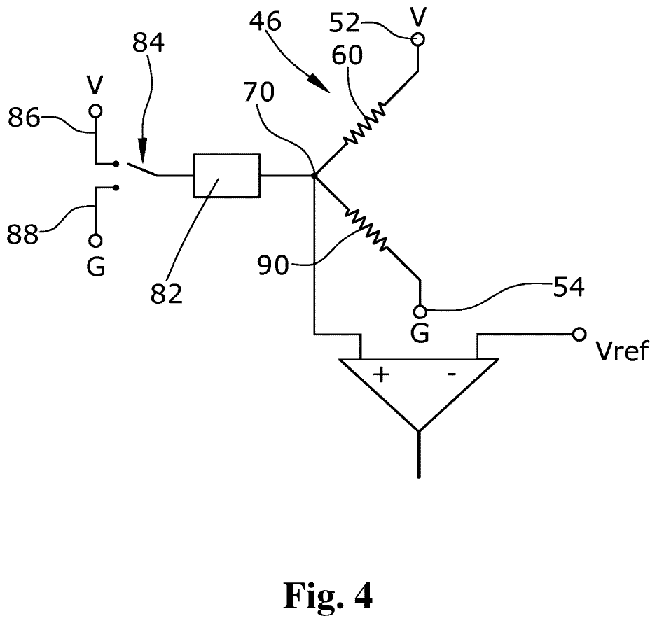

Another embodiment of the present invention is shown in FIG. 4 where the magnetoresistive sensor unit 40 comprises only a voltage divider 46 comprising a single magnetoresistive element 60 and a resistor 90 with a fixed resistance value. The magnetoresistive element 60 and the resistor 90 are connected in series, wherein the measuring point 70 is arranged therebetween. The measuring point 70 is electrically connected to the additional resistor 82. The additional resistor 82 is electrically connected to a switching unit 84 as in the previously described embodiment. To determine the direction of rotation, the measured value at the measuring point 70 is compared with a predefined voltage value Vref, wherein the direction of rotation is inferred depending on whether the measured value is greater or less than the predefined voltage value Vref. The measured value at one of the two measuring points 70, 72 could also analogously be compared with a predefined voltage value Vref in the version shown in FIG. 2 instead of comparing the two measuring points 70, 72, thereby indicating the direction of rotation of the shaft 12.

The present invention is not limited to embodiments described herein; reference should be had to the appended claims.

### LIST OF REFERENCE CHARACTERS

8 Measuring arrangement
10 Measuring system
12 Shaft/Object
14 Drive motor
16 Motor housing
18 Rotor unit
20 Stator unit
22 Magnetic shielding arrangement
24 Rotor plate
25 Exciter unit
26 Exciter magnet
32 Stator plate
34 Sensor device
36 Wiegand sensor
40 Magnetoresistive sensor unit
42 Wiegand wire
44 Coil arrangement
46 Voltage divider
50 Bridge circuit
52 First connection
54 Second connection
56 First bridge branch/Bridge branch
58 Second bridge branch/Bridge branch
60 Magnetoresistive element
62 Magnetoresistive element
64 Magnetoresistive element

1-7. (canceled)

8: A measuring arrangement comprising:
an object which is configured to rotate around a rotational axis or which is configured to be translationally movable; and
a measuring system which is configured to measure a movement of the object, the measuring system comprising,
an exciter unit which is connected to the object, the exciter unit comprising at least one permanent-magnet exciter magnet,
a Wiegand sensor which is configured to interact with a magnetic field of the at least one permanent-magnet exciter magnet,
a magnetoresistive sensor unit which is configured to interact with the magnetic field of the at least one permanent-magnet exciter magnet and which is arranged at least one of offset and rotated relative to the Wiegand sensor, the magnetoresistive sensor unit comprising at least one voltage divider which comprises a first connection and a second connection for supplying the at least one voltage divider, at least one magnetoresistive element, and at least one measuring point,
a third connection,
a fourth connection,
a switching unit which is electrically connected to the Wiegand sensor, and
an additional resistor which is electrically connected to the at least one measuring point and which is configured to be electrically connected via the switching unit either to the third connection or to the fourth connection,
wherein,
the switching unit is configured to evaluate voltage pulses of the Wiegand sensor so that a switching between the third connection and the fourth connection takes place as a function of a polarity of the voltage pulses of the Wiegand sensor.

9: The measuring arrangement as recited in claim 8, wherein,
the third connection is electrically connected to the first connection, and
the fourth connection is electrically connected to the second connection.

10: The measuring arrangement as recited in claim 8, wherein,
the at least one voltage divider of the magnetoresistive sensor unit is provided as a first voltage divider and a second voltage divider,
the first voltage divider and the second voltage divider together form a bridge circuit which comprises a first bridge branch and a second bridge branch which are connected in parallel,
the first bridge branch comprises two of the at least one magnetoresistive element which are connected in series, and one of the at least one measuring point which is arranged between the two of the at least one magnetoresistive element,
the second bridge branch comprises two of the at least one magnetoresistive element which are connected in series, and one of the at least one measuring point which is arranged between the two of the at least one magnetoresistive element, and
the one of the at least one measuring point of the first branch or of the second branch is electrically connected to the additional resistor.

11: The measuring arrangement as recited in claim 8, wherein,
the at least one voltage divider further comprises a resistor having a fixed resistance value,
the at least one magnetoresistive element and the resistor are connected in series, and
the at least one measuring point is arranged between the at least one magnetoresistive element and the resistor.

12: The measuring arrangement as recited in claim 8, wherein,
a voltage pulse of the Wiegand sensor caused in a first direction of the rotating or translationally moving object at a first position, and a voltage pulse of the Wiegand sensor caused in a second direction which is opposite to the first direction of the rotating or translationally moving object at a second position, comprise a same polarity, and
the magnetoresistive sensor unit is further configured to provide a sensor signal having a negative value at the first position and a positive value at the second position.

13: The measuring arrangement as recited in claim 8, wherein,
a voltage pulse of the Wiegand sensor caused in a first direction of the rotating or translationally moving object at a first position, and a voltage pulse of the Wiegand sensor caused in a second direction which is opposite to the first direction of the rotating or translationally moving object at a second position, comprise a same polarity,
at the first position, a first measured value of the at least one measuring point is greater than a predefined voltage value, and
at the second position, a second measured value of the at least one measuring point is less than the predefined voltage value.

14: The measuring arrangement as recited in claim 8, wherein the magnetoresistive sensor unit is a TMR sensor or a GMR sensor.
